(19) United States
(12) Patent Application Publication
(10) Pub. No.: US 2008/0217761 A1
(43) Pub. Date: Sep. 11, 2008

(54) Structure of semiconductor device package and method of the same

(75) Inventors: Wen-Kun Yang, Hsin-Chu City (TW); Chih-Ming Chen, Sinpu Twonship (TW); Hsien-Wen Hsu, Lujhou City (TW)

Correspondence Address: BIRCH STEWART KOLASCH & BIRCH, PO BOX 747, FALLS CHURCH, VA, 22040-0747, US

(73) Assignee: Advanced Chip Engineering Technology Inc.

(21) Appl. No.: 11/715,358

(22) Filed: Mar. 8, 2007

(51) Int. Cl. H01L 23/053

(52) U.S. Cl. 257/700; 257/737; 361/748; 438/107; 257/E23.188; 257/E21.001

(57) ABSTRACT

The present invention provides a semiconductor device package comprising a substrate with at lease a pre-formed die receiving cavity formed and terminal contact metal pads formed within an upper surface of the substrate. At lease a first die is disposed within the die receiving cavity. A first dielectric layer is formed on the first die and the substrate and refilled into a gap between the first die and the substrate to absorb thermal mechanical stress there between. A first re-distribution layer (RDL) is formed on the first dielectric layer and coupled to the first die. A second dielectric layer is formed on the first RDL, and then a second die is disposed on the second dielectric layer and surrounded by core pastes having through holes thereon. A second re-distribution layer (RDL) is formed on the core pastes to fill the through holes, and then a third dielectric layer formed on the second RDL.

### BACKGROUND OF THE INVENTION

1. Field of the Invention

This invention relates to a semiconductor device package, and more particularly to a structure of semiconductor device multi chips package with good CTE matching and method of the same, the multi chips package structure can simplify the process to avoid die shift and warp issue during process.

2. Description of the Prior Art

In recent years, the high-technology electronics manufacturing industries launch more feature-packed and humanized electronic products. Rapid development of semiconductor technology has led to rapid progress of a reduction in size of semiconductor packages, the adoption of multi-pin, the adoption of fine pitch, the minimization of electronic components and the like. The purposes and the advantages of wafer level package includes decreasing the production cost, decreasing the effect caused by the parasitic capacitance and parasitic inductance by using the shorter conductive line path, acquiring better SNR (i.e. signal to noise ratio).

In the field of semiconductor devices, the device density is increased and the device dimension is reduced, continuously. The demand for the packaging or interconnecting techniques in such high density devices is also increased to fit the situation mentioned above. Conventionally, in the flip-chip attachment method, an array of solder bumps is formed on the surface of the die. The formation of the solder bumps may be carried out by using a solder composite material through a solder mask for producing a desired pattern of solder bumps. The function of chip package includes power distribution, signal distribution, heat dissipation, protection and support . . . and so on. As a semiconductor become more complicated, the traditional package technique, for example lead frame package, flex package, rigid package technique, can't meet the demand of producing smaller chip with high density elements on the chip.

In the manufacturing method, wafer level chip scale package (WLCSP) is an advanced packaging technology, by which the die are manufactured and tested on the wafer, and then singulated by dicing for assembly in a surface-mount line. Because conventional package technologies have to divide a dice on a wafer into respective dies and then package the die respectively, therefore, these techniques are time consuming for manufacturing process. Since the chip package technique is highly influenced by the development of integrated circuits, therefore, as the size of electronics has become demanding, so does the package technique. For the reasons mentioned above, the trend of package technique is toward ball grid array (BGA), flip chip (FC-BGA), chip scale package (CSP), Wafer level package (WLP) today. “Wafer level package” is to be understood as meaning that the entire packaging and all the interconnections on the wafer as well as other processing steps are carried out before the singulation (dicing) into chips (dies). Generally, after completion of all assembling processes or packaging processes, individual semiconductor packages are separated from a wafer having a plurality of semiconductor dies. The wafer level package has extremely small dimensions combined with extremely good electrical properties.

WLP technique is an advanced packaging technology, by which the die are manufactured and tested on the wafer, and then singulated by dicing for assembly in a surface-mount line. Because the wafer level package technique utilizes the whole wafer as one object, not utilizing a single chip or die, therefore, before performing a scribing process, packaging and testing has been accomplished; furthermore, WLP is such an advanced technique so that the process of wire bonding, die mount and tinder-fill can be omitted. By utilizing WP technique, the cost and manufacturing time can be reduced, and the resulting stricture of WLP can be equal to the die; therefore, this technique can meet the demands of miniaturization of electronic devices.

Though the advantages of WLP technique mentioned above, some issues still exist influencing the acceptance of WLP technique. For instance, the coefficient of thermal expansion (CTE) difference (mismatching) between the materials of a structure of WLP becomes another critical factor to mechanical instability of the structure. A package scheme disclosed by US Patent Application No. 2005/0124093 suffers the CTE mismatching issue. It is because the prior art uses silicon die encapsulated by molding compound. As known, the CTE of silicon material is 2.3, but the CTE of molding compound is around 20-180. The arrangement causes chip location be shifted during process due to the curing temperature of compound and dielectric layers materials are higher and the inter-connecting pads will be shifted that will causes yield and performance problem. It is difficult to return the original location during temperature cycling (it caused by the epoxy resin property if the curing Temp near/over the Tg). It means that the prior structure package can not be processed by large size, and it causes higher manufacturing cost.

Further, some technical involves the usage of die that directly formed on the upper surface of the substrate. As known, the pads of the semiconductor die will be redistributed through redistribution processes involving a redistribution layer (RDL) into a plurality of metal pads in an area array type. The build up layer will increase the size of the package. Therefore, the thickness of the package is increased. This may conflict with the demand of reducing the size of a chip.

Further, the prior art suffers complicated process to form the “Panel” type package. It needs the mold tool for encapsulation and the injection of mold material. It is unlikely to control the surface of die and compound at same level due to warp after heat curing the compound, the CMP process may be needed to polish the uneven surface. The cost is therefore increased.

In view of the aforementioned, the present invention provides a structure of semiconductor device package with good CTE performance and shrinkage size to overcome the above problem and also provide the better board level reliability test of temperature cycling.

### SUMMARY OF THE INVENTION

The present invention will descript some preferred embodiments. However, it is appreciated that the present invention can extensively perform in other embodiments except for these detailed descriptions. The scope of the present invention is not limited to these embodiments and should be accorded the following claims.

One objective of the present invention is to provide a structure of semiconductor device multi chips package and method of the same, which can simplify the process, and easy to control the roughness of device surface and the thickness of die attached material.

Another objective of the present invention is to provide a structure of semiconductor device multi chips package and method of the same, which can avoid die shift issue during process.

Still another objective of the present invention is to provide a structure of semiconductor device multi chips package and method of the same, which can allow no injection mold tool during process.

Yet another objective of the present invention is to provide a structure of semiconductor device multi chips package and method of the same, which can avoid warp during process.

Another objective of the present invention is to provide a structure of semiconductor device multi chips package and method of the same, which can avoid the Chemical Mechanical Polish (CMP) process on the device surface.

The present invention provides a structure of semiconductor device multi chips package comprising a substrate with at least a pre-formed die receiving cavity and terminal contact pads formed within an upper surface of substrate; at least first die disposed within the die receiving cavity by adhesion; a first dielectric layer formed on the first die and the substrate and refill into a gap between the first die and the sidewall of receiving cavity of the substrate to absorb thermal mechanical stress there between; a first re-distribution layer (RDL) formed on the first dielectric layer and coupled to the first die; a second dielectric layer formed on the first RDL; a second die disposed on the second dielectric layer and surrounded by core pastes having a through hole thereon; a second re-distribution layer (RDL) formed on the core pastes to fill the through hole and coupled to the second die; and a third dielectric layer formed on the second RDL; wherein the first die and the second die respectively having pluralities of pads coupled to the first RDL and the second RDL for electrical connection with each other by the through hole.

The present invention provides a method for forming a semiconductor device multi chips package comprising providing a substrate with a pre-formed die receiving cavity and terminal contact pads formed within an upper surface of the substrate; using a pick and place fine alignment system to re-distribute known good dice on a die redistribution tool with desired pitch, wherein the die redistribution tool includes alignment pattern, the pattern glues on it, and the active surface of the first die be stuck on the pattern glues; attaching a first die attached material on die back side; bonding the substrate on to the die back side, and curing; then, printing the adhesive material at the peripheral area of the carrier tool to adhere the substrate; then separating the tool from the substrate; coating a first dielectric layer on the first die and the substrate, followed by performing vacuum procedure to fill into the gap between the first die and the sidewall of die receiving cavity; forming the opening on both the I/O pads of the first die and the contact pads of upper surface of substrate; forming a first re-distribution layer (RDL) on the first dielectric layer and coupling to the first die; forming a second dielectric layer to cover the first RDL; attaching a second die on the second dielectric layer covered by core pastes having a through hole; forming a second re-distribution layer (RDL) to couple the second die and fill the through hole to electrical connect to the first RDL; and forming a third dielectric layer over the second RDL; wherein the first die and the second die respectively having pluralities of pads coupled to the first RDL and the second RDL can be electrical connected with each other by the through hole.

### BRIEF DESCRIPTION OF THE DRAWINGS

The foregoing aspects and many of the attendant advantages of this invention will become more readily appreciated as the same becomes better understood by reference to the following detailed description, taken in conjunction with the accompanying drawings, wherein:

FIG. 1 illustrates a cross-section diagram of a semiconductor device package with stacking chips according to the present invention;

FIG. 2 illustrates a cross-section diagram of a semiconductor device package with stacking chips and pluralities of soldering balls according to the present invention;

FIG. 3 illustrates a cross-section diagram of a semiconductor device package with a side-by-side structure according to one embodiment of the present invention;

FIG. 4 illustrates a cross-section diagram of a semiconductor device package with a side-by-side and stacking structure according to another embodiment of the present invention;

FIG. 5a illustrates a cross-section diagram of a semiconductor device multi chips package one embodiment of according to the present invention;

FIG. 5b illustrates a cross-section diagram of a semiconductor device multi chips package with a substrate having a pre-formed die receiving cavity according to the present invention;

FIG. 6a-6c illustrate a cross-section diagram of the combination of the substrate and the tool according to the present invention;

FIG. 7 illustrates a top view diagram of the combination of the substrate and the tool according to the present invention; and

FIG. 8 illustrates a cross-section view diagram of the combination of the multi chips package attached on the PCB or Mother Board according to the present invention.

### DESCRIPTION OF THE PREFERRED EMBODIMENT

In the following description, numerous specific details are provided in order to give a through understanding of embodiments of the invention. Referring now to the following description wherein the description is for the purpose of illustrating the preferred embodiments of the present invention only, and not for the purpose of limiting the same. One skilled in the relevant art will recognize, however, that the invention may be practiced without one or more of the specific details, or with other methods, components, materials, etc.

The present invention discloses a structure of semiconductor device package utilizing a substrate having predetermined terminal contact metal pads formed thereon and a pre-formed cavity formed into the substrate. A die is disposed within the die receiving cavity by adhesion. A photosensitive material is coated over the die and the pre-formed substrate. Preferably, the material of the photosensitive material is formed of elastic material.

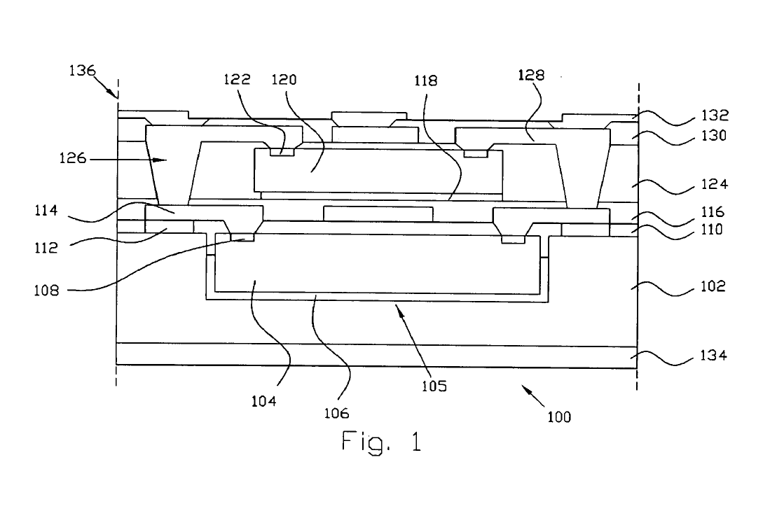

Referring to FIG. 1, it is a cross-section diagram of a semiconductor device package according to the present invention. The semiconductor device package 100 comprises a substrate 102, a first die 104 and a second die 120, a die receiving cavity 105, a first die attached material 106 and a second die attached material 118, a first, second and third dielectric layer 110, 116 and 130, core pastes 124, a through hole 126, a first redistribution layer (RDL) 114, a second redistribution layer (RDL) 128, a cover layer 134, terminal pads 132 and a plurality of soldering bumps 138.

In FIG. 1, the substrate 102 has a die receiving cavity 105 pre-formed within an upper surface of the substrate 102 to receive a first die 104. A cover layer 134 is formed under the lower surface of the substrate 102 for laser mark or protection. The material of cover layer 134 includes epoxy.

The first die 104 is disposed within the die receiving cavity 105 on the substrate 102 and fixed by the first die attached material 106 (preferably, elastic based materials). As know, pluralities of bonding pads 108 are formed within an upper surface of the first die 104. A first dielectric layer 110 is formed over the first die 104 and filling into the space between the first die 104 and the sidewalls of the die receiving cavity 105. Pluralities of openings are formed within the first dielectric layer 110 through the lithography process or exposure and develop procedure. The pluralities of openings are aligned to the bonding pads or I/O pads 108 and terminal contact metal pads 112, respectively.

The first RDL (re-distribution layer) 114, also referred to as conductive trace 114, is formed on the first dielectric layer 110 by removing (seed layers) selected portions of metal layer formed over the first dielectric layer 110, wherein the first RDL 114 keeps electrically connected with the first die 104 through the I/O pads 108 and terminal contact metal pads 112. A part of the material of the first RDL 114 will re-fills into the openings in the first dielectric layer 110. Then, the second dielectric layer 116 is formed on the first dielectric layer 110 and the first RDL 114, that is to say, the second dielectric layer 116 is filled into a space between the first RDL 114.

A second die 120 is disposed on the second dielectric layer 116 after attaching a second die attached layer 118 on the second dielectric layer 116 by approximately aligning to the first die 104, it maybe the same kind of material for both die attached layer 118 and the second dielectric layer 1116. As know, pluralities of bonding pads 122 are formed within an upper surface of the second die 120. The core pastes 124 are formed over the second die 122 and filling into the space of the lower side of the second die 120 except the second die attached material 118. Pluralities of openings are formed through the lithography process or exposure and develop procedure or laser drill process, and aligned to the bonding pads or I/O pads 122. It is noted that the core pastes 124 further have a through hole 126 formed thereon that can be communicated with the first RDL 114. A second RDL 128 is formed on the core pastes 124 and filled into the through hole 126 to couple to the first RDL 114. In other words, the first RDL 114 and the second RDL 128 can be electrical connected with each other by the through hole 126 filled by the second RDL 128. The first RDL 114 and the second RDL 128 are respectively coupled to the first die 104 and the second die 120, so that the first die 104 and the second die 120 can be coupled to the first RDL 114 and the second RDL 128 by the through hole 126.

A third dielectric layer 130 is formed on the second RDL 128, and then the core pastes 124, and pluralities of opening are formed on the second RDL 128. Terminal pads 132 are located on the third dielectric layer 130 and connected to the second RDL 128, and connected to the first RDL 114 and terminal contact metal pads 112 of substrate 102. A scribe line 136 is defined between each unit of package 100 for separating each unit.

In one embodiment, the first dielectric layer 110, the second dielectric layer 116 and the third dielectric layer 130 include an elastic dielectric layer, a photosensitive layer, a silicone dielectric based layer, a siloxane polymer (SINR) layer, a polyimides (PI) layer or silicone resin layer. The materials are preferably an elastic dielectric material which is made by silicone dielectric based materials comprising siloxane polymers (SINR), Dow Corning WL5000 series, and composites thereof. In another embodiment, the first, second and third dielectric layer 110, 116 and 130 are made by a material comprising, polyimides (PI) or silicone resin. Preferably, it is a photosensitive layer for simple process.

In one embodiment, the materials of the first RDL 114 and the second RDL 128 are made from an alloy comprising Ti/Cu/Au alloy or Ti/Cu/Ni/Au alloy. Further, a seed metal layer (not shown) is sputtered within (part of) the first RDL 114 and the second RDL 128 (part of RDL).

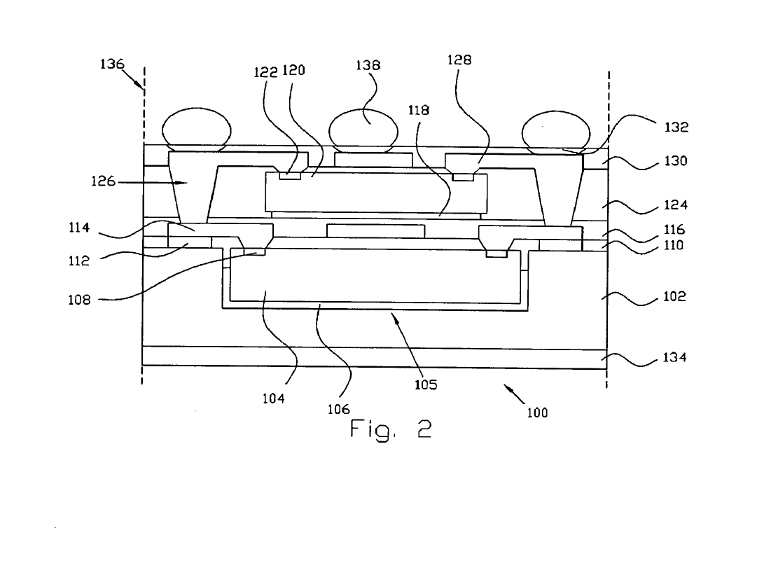

The first dielectric layer 110 is formed atop of the first die 104 and substrate 102 and fills the space surrounding the first die 104; due to the first dielectric layer 110 is elastic property, it acts as butter area can absorb the thermal mechanical stress between the first die 104 and the substrate 102 during temperature cycling. The aforementioned stacking structure constricts Land Grid Array (LGA) type package. An alternative embodiment can be seen in FIG. 2, Conductive balls or soldering bumps 138 are formed on the terminal pads 132. This type is called ball grid array (BGA) type package. The other parts are similar to FIG. 1, therefore, the detailed description is omitted. The terminal pads 132 act as the UBM (under ball metal) under the BGA scheme. Pluralities of terminal contact conductive pads 132 are formed on the second RDL 128.

Preferably, the material of the substrate 102 is organic substrate likes FR4, FR5, BT, print circuit board (PCB) with defined cavity or Alloy 42 with pre etching circuit. Preferably, the organic substrate with high glass transition temperature (Tg) are epoxy type FR5 or BT (Bismaleiniide triazine) type substrate. The material of the substrate 102 also can be metal, alloy, glass, silicon, ceramic. The Alloy 42 is composed of 42 % Ni and 58% Fe. Kovar can be used also, and it is composed of 29% Ni, 17% Co, 54 % Fe. The glass, ceramic, silicon can be used as the substrate. It is noted that the materials of the present invention are only used to illustrate rather than limit the present invention.

It is because that the coefficient of thermal expansion (CTE) (X/Y direction) of the epoxy type organic substrate (FR5/BT) is around 16 and the CTE of the tool of chip redistribution around is around 5 to 8 by employing the glass materials as the tool. But once use the FR5/BT as the material of die redistribution tool, then, the die shift may not be the concern due to CTE are identical on both substrate and die redistribution tool. The FR5/BT can not return to original location after the temperature cycling (near to Glass transition temperature Tg) that causes the die shift in panel form during the WLP process which needs several high temperature process. For example, the dielectric layers formation, the heat curing die attached materials etc., the following process steps and tool are to make sure organic substrate can keep the original location and no any warp happen during process by using the glass as tool.

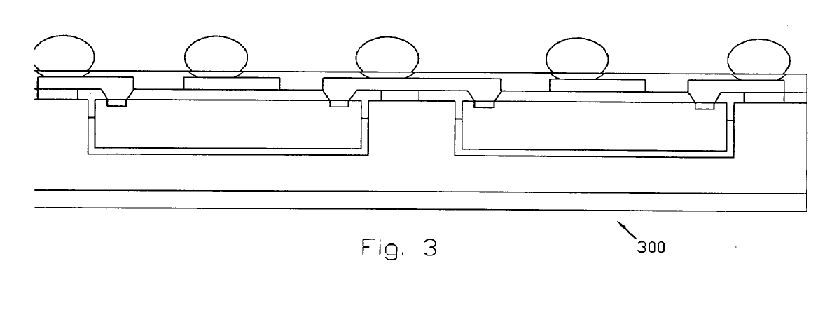

Please refer to FIG. 3, it illustrates a cross-section diagram of a semiconductor device package with a side-by-side structure according to one embodiment of the present invention. The present invention further provides a side-by-side structure 300 which has multiple dice arranged side by side with each other.

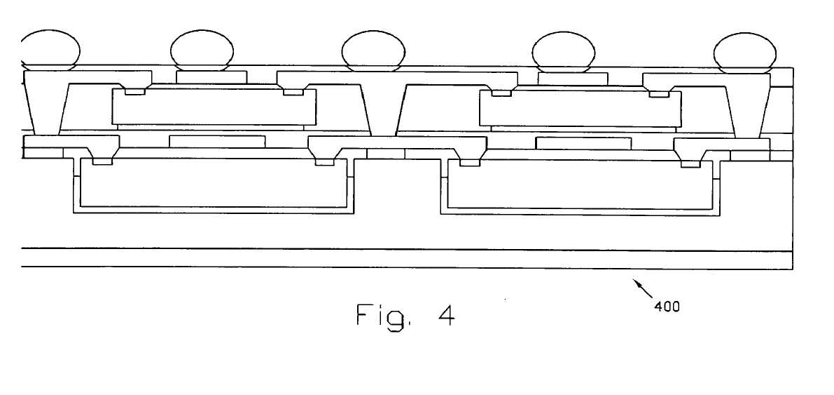

Refer to FIG. 4, illustrates a cross-section diagram of a semiconductor device package with a side-by-side and stacking structure according to another embodiment of the present invention. The present invention also provides a side-by-side and stacking structure 400 which has multiple dice arranged side by side and stacking with each other.

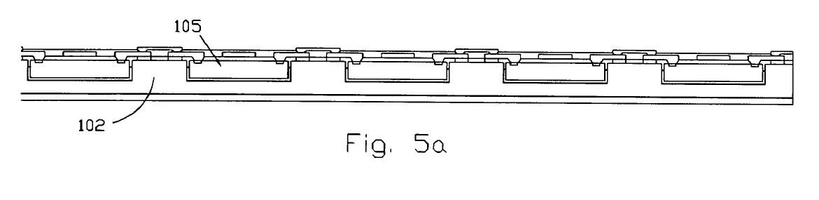

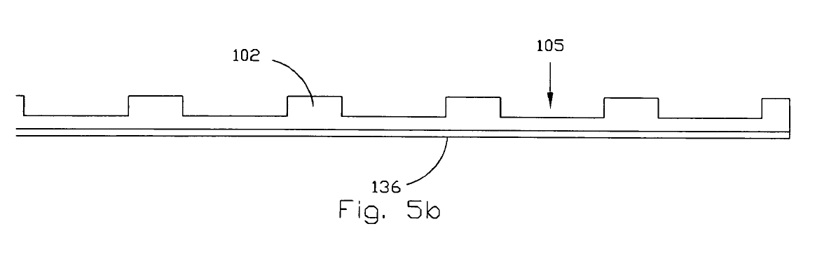

As shown in FIG. 5a, the substrate 102 could be round type such as wafer type, the diameter could be 200, 300 mm or higher. It could be employed for rectangular type such as panel form. FIG. 5a illustrates the substrate 102 for the panel wafer form after process but before singulation. As can be seen from the drawings, the substrate 102 is pre-formed with the die receiving cavities 105. In FIG. 5a, the package units of FIG. 1 are arranged in a matrix form. Refer to FIG. 5b, it illustrates a semiconductor device package with a substrate 102 having a pre-formed die receiving cavity 105, and the cover layer 136 is formed on the lower surface of the substrate 102.

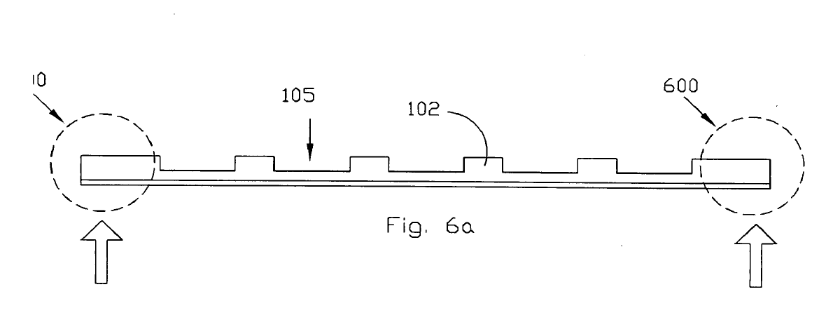

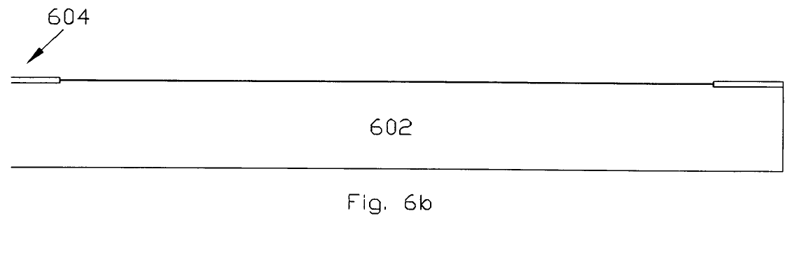

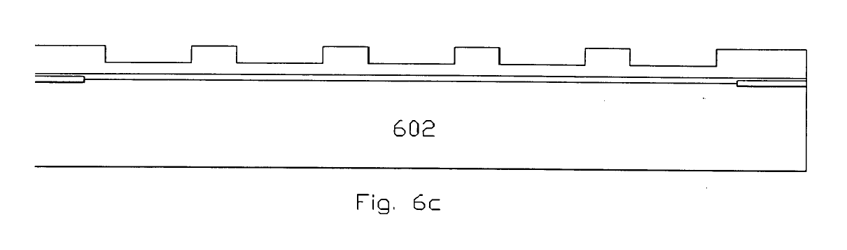

Please refer to FIG. 6a, there is no die receiving cavity 105 formed at the peripheral (edge) area 600 of the substrate 102. A die redistribution tool 602, such as glass carrier tool, with adhesive material (preferably UV curing type) 604 formed at the peripheral area 600 of the glass tool 602 for (adhesion) handling organic substrate 102 during WLP process, as shown in FIG. 6b. FIG. 6c is the combination of the glass carrier tool 602 and the substrate 102 after vacuum bonding and UV curing.

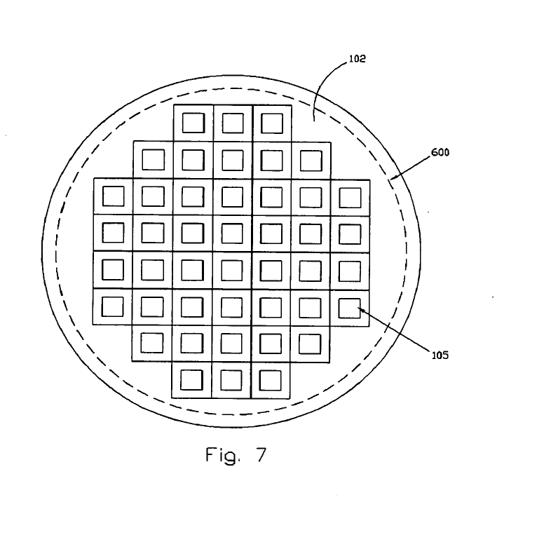

Refer to FIG. 7, it shows that the edge area of substrate 102 does not include the die receiving cavity 105, and the periphery area 600 will be used for sticking the glass carrier tool 602 (wherein the materials of carrier tool maybe glass, silicon, ceramic, PCB and alloy 42 that the CTE matching to die redistribution tool, it prefers to use the same kinds of material for both substrate and die redistribution tool to overcome the die shift issue due to high temperature curing) during WLP process. The substrate 102 will be adhered with glass carrier tool 602 and it will be stuck and hold the substrate 102 during process. After the WLP process is completed, the area 600 indicated by the dot line will be cut from the glass carrier tool 602, it means that the inner area defined by the dot line will be performed the sawing process for package singulation.

In one embodiment of the present invention, the elastic dielectric layer is a kind of material with CTE larger than 100 (ppm/° C.), elongation rate about 40 percent (preferably 30 percent-50 percent), and the hardness of the material is between plastic and rubber. The thickness of the elastic dielectric layer depends on the stress accumulated in the RDL/dielectric layer interface during temperature cycling test.

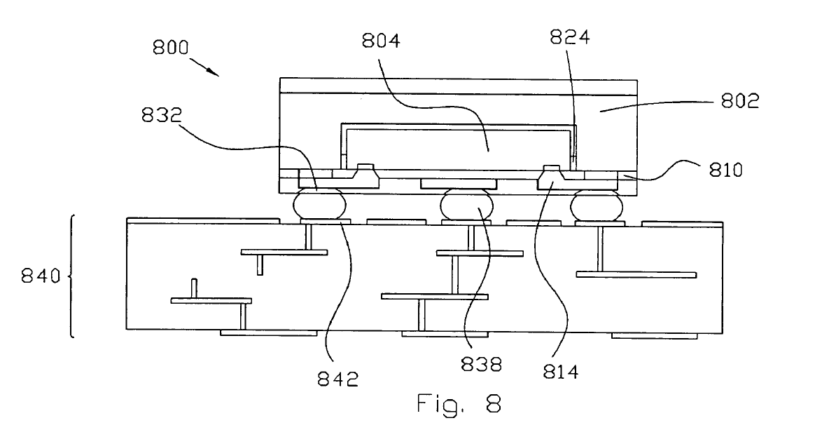

FIG. 8 illustrates a cross-section view diagram of the combination of the package 800 attached on the PCB or Mother Board 840. In FIG. 8, it illustrates the major portions that associate with the CTE issue. The silicon die 804 (CTE is 2.3) is packaged inside the package. FR5 or BT organic epoxy type material (CTE is approximately 16) is employed as the substrate 802 and its CTE is the same as the PCB or Mother Board 840. The gap 824 between the die 804 and the substrate 802 is filled with elastic materials to absorb the thermal mechanical stress due to CTE mismatching (between die and the FR5/BT). Further, the dielectric layers 810 include elastic materials to absorb the stress between the die pads 838 and the PCB 840. The RDL metal 814 is Cu/Au materials and the CTE is around 16 that is the same as the PCB 840 and organic substrate 802, and the UBM 832 of contact bump be located on the terminal contact metal pads of substrate 802. The metal land of PCB 842 is Cu, and the CTE of Cu is around 16 that is match to the one of PCB 840. From the description above, the present invention may provide excellent CTE solution for the Fan-out WLP.

Apparently, CTE matching issue under the build up layers (PCB and substrate) is solved by the present scheme and it provides better reliability (no thermal stress in X/Y direction-on board) and the elastic DL is employed to absorb the Z direction stress. Only one material (Epoxy type) is involves the singulation. The gap 824 between chip edge and cavity sidewall can be used to fill the elastic dielectric materials to absorb the mechanical/thermal stress.

In one embodiment, the thickness of the first RDL 114 and the second RDL 128 is between 2 μm and 15 μm. The Ti/Cu alloy is formed by sputtering technique also as seed metal layers, and the Cu/Au or Cu/Ni/Au alloy is formed by electroplating; exploiting the electroplating process to form the first RDL 114 and the second RDL 128 can make the first RDL 114 and the second RDL 128 thick enough to withstand CTE mismatching during temperature cycling. The metal pads 138 can be Al or Cu or combination thereof. If the structure of semiconductor device utilizes SINR as the elastic dielectric layer and Cu as the RDL, according the stress analysis not shown here, the stress accumulated in the RDL/dielectric layer interface is reduced.

As shown in FIG. 1-5a, the first RDL 114 and the second RDL 128 respectively fans out of the first die 104 and the second die 120 and coupled with each other by the through hole 126 to communicate toward the terminal pads 132. It is different from the prior art technology, the first die 104 is received within the pre-formed cavity 105 of the substrate 102, thereby reducing the thickness of the package. The prior art violates the rule to reduce the die package thickness. The package of the present invention will be thinner than the prior art. Further, the substrate 102 is pre-prepared before package. The die receiving cavity 105 is pre-determined. Thus, the throughput will be improved than ever. The present invention discloses a fan-out WLP with reduced thickness and good CTE performance.

According to the aspect of the present invention, the present invention further provides a method for forming a semiconductor device multi chips package. The steps are illustrated as follows.

A substrate 102 with a pre-formed die receiving cavity 105 and terminal contact pads 112 formed within an upper surface of the substrate 102 is provided. Then, using a pick and place fine alignment system to re-distribute at least the first die 104 on a die redistribution tool (do not shown) with desired pitch (the die redistribution tool with alignment pattern and patterned glues for sticking the active surface of the first die 104). The carrier tool 602 includes adhesive material 604 at the peripheral area 600 of the carrier tool 602 to adhere the substrate 102. Next, printing the attached material 106 on the back side of first die 104. The substrate 102 with the carrier tool 602 are bonded on to the back side of the first die 104, and vacuum cured then separating the die redistribution tool from the substrate 102 with the first die 104 and the carrier tool 602. A first dielectric layer 110 is coated on the first die 104 and the substrate 102, followed by performing vacuum procedure. A first re-distribution layer (RDL) 114 is formed on the first dielectric layer 110 and coupling to the first die 104. A second dielectric layer 116 is formed to cover the first RDL 114 and the first dielectric layer 110.

Sequentially, at least the second die 120 is disposed on the second dielectric layer 116 covered by core pastes 124 having through holes 126. A second re-distribution layer (RDL) 128 is formed to couple the second die 120 and fill the through holes 126 to electrical connect to the first RDL 114. A third dielectric layer 130 is formed over the second RDL 128. The first die 104 and the second die 120 respectively have pluralities of pads 108 and 122 coupled to the first RDL 114 and the second RDL 128 can be electrical connected with each other by the through holes 126. Then, a plurality of soldering balls 138 are welded on the second RDL 128.

Before forming the first RDL 114, a seed metal layer (not shown) is sputtered on the surfaces of the first dielectric layer 110, the contact metal pads 112 and the bonding pads 108. Similarly, a seed metal layer is also sputtered on the surfaces of the core pastes 124, the bonding pads 122 and the internal side surfaces of the through holes 126 before forming the second RDL 128. The material of the seed metal layer includes Ti/Cu. Next, coating the photo resist layer (not shown) on the seed metal layer, and photo masking the photo resist layer to form the first RDL 114 and the second RDL 128. A Cu/Au or Cu/Ni/Au film is electro-plating on the surface of the package. Then, the photo resist layer is stripped and the seed metal layer is removed by a wet etching method to form the RDL on the surface the package.

It is noted that the material and the arrangement of the structure are illustrated to describe but not to limit the present invention. The material and the arrangement of the structure can be modified according to the requirements of different conductions.

The process for the present invention includes providing a die redistribution tool with alignment pattern formed thereon. Then, the patterned glues is printed on the tool (be used for sticking the surface of dice), followed by using pick and place fine alignment system with flip chip function to re-distribute the known good dies on the tool with desired pitch. The pattern glues will stick the chips on the tool. Subsequently, the first die attached materials is printed on the back side of the first die (preferably, the elastic based materials). Then, the panel bonder is used to bond the substrate on to die back side; the tipper surface of substrate except the die receiving cavities also be stuck on the pattern glues, then vacuum curing and separate the tool with panel wafer.

Alternatively, the die bonder machine with fine alignment is employed, and the first die attached materials is dispensed on the die receiving cavity 105 of substrate 102 or the first die 104 with attached tape on the back side. The first die 104 is placed on to the die receiving cavity 105 of substrate 102. The first die attached materials 106 is thermally cured to ensure the first die 104 is attached on the substrate 102.

Once the die is re-distributed on the substrate, then, a clean up procedure is performed to clean the dice surface by wet and/or dry clean. Next step is to coat the first dielectric materials on the panel, followed by performing vacuum procedure to ensure there is no bubble within the panel. Subsequently, lithography process is performed to open via (contact metal pads) and Al bonding pads and/or the scribe line (optional), or the laser drill method also can be performed. Plasma clean step is then executed to clean the surface of via holes and Al bonding pads. Next step is to sputter Ti/Cu as seed metal layers, and then Photo Resistor (PR) is coated over the dielectric layer and seed metal layers for forming the patterns of redistributed metal layers (RDL). Then, the electro plating is processed to form Cu/Au or Cu/Ni/Au as the RDL metal, followed by stripping the PR and metal wet etching to form the RDL metal trace. Subsequently, the next step is to coat or print the top dielectric layer and to open the contact bump via to form the UBM and/or to open the scribe line (optional).

After the ball placement or solder paste printing, the heat re-flow procedure is performed to re-flow on the substrate side (for BGA type). The testing is executed. Panel wafer level final testing is performed by using vertical probe card. After the testing, the substrate is sawed to singular the package into individual units. Then, the packages are respectively picked and placed the package on the tray or tape and reel.

According to the aspect of the present invention, the advantages of the present invention are as follows. The process is simple for forming panel wafer type and is easy to control the roughness of panel surface for wafer level process. The thickness of panel (die attached) is easy to be controlled and die shift issue will not occurs during process. The injection mold tool is omitted and warp and CMP polish process will not be introduced either. Further, the substrate is pre-prepared with pre-form die receiving cavity and terminal contact metal pads (for organic substrate); the size of cavity equals to the die size +plus around 50 μm to 100 μm per/side. It can be used as stress buffer releasing area by filling the elastic dielectric materials to absorb the thermal stress due to the CTE difference between silicon die and substrate (FR5/BT)). The packaging throughput will be increased (manufacturing cycle time was reduced) due to apply the simple build up layers on top the surface of die. The terminal pads are formed on the same surface to the dice active surface.

Moreover, the dice placement process is the same as the current process. No core paste (resin, epoxy compound, silicone rubber, etc.) filling is necessary for the present invention. CTE mismatching issue is overcome during panel form process and the deepness between die and substrate FR4 is only around 20-50 μm (act as die attached thickness), the surface level of die and substrate can be the same after the die is attached on the die receiving cavities of substrate. Only silicone dielectric material (preferably silicone based—SINR) is coated on the active surface and the substrate (preferably FR5 or BT) surface. The contact pads are opened by using photo mask process only due to the dielectric layer (SINR) is photosensitive layer for opening the contacting open. Vacuum process during SINR coating is used to eliminate the bubble issue during filling the gap between die and side wall of cavity of substrate. The die attached material is printed on the back-side of dice before substrate be bonded together with dice (chips). The reliability for both package and board level is better than ever, especially, for the board level temperature cycling test, it was due to the CTE of substrate and PCB mother board are identical, hence, no thermal mechanical stress be applied on the solder bumps/balls; the previous failure mode (solder ball crack) during temperature cycling on board test were not obvious. The cost is low and the process is simple. It is easy to form the multi chips package.

Accordingly, the structure of semiconductor device multi chips package and method of the same disclosed by the present invention can provide unexpected effect than prior art, and solve the problems of prior art. It is noted that the method may apply to wafer or panel (LCD display, print circuit board/substrate) industry and also can be applied and modified to other related applications.

As will be understood by a person skilled in the art, the foregoing preferred embodiments of the present invention are illustrative of the present invention, rather than limiting the present invention. Having described the invention in connection with a preferred embodiment, modification will suggest itself to those skilled in the art. Thus, the invention is not to be limited by this embodiment. Rather, the invention is intended to cover various modifications and similar arrangements included within the spirit and scope of the appended claims, the scope of which should be accorded the broadest interpretation so as to encompass all such modifications and similar structures.

What is claimed is:

1. A structure of semiconductor device package, comprising:
a substrate with at least a pre-formed die receiving cavity and terminal contact pads formed within an upper surface of said substrate;
at least a first die disposed within said die receiving cavity;
a first dielectric layer formed on said first die and said substrate and refill into a gap between said first die and said substrate to absorb thermal mechanical stress there between;
a first re-distribution layer (RDL) formed on said first dielectric layer and coupled to said first die;
at least a second dielectric layer formed on said first RDL;
a second die disposed on said second dielectric layer and surrounded by core pastes having through holes thereon;
a second re-distribution layer (RDL) formed on said core pastes to fill said through holes; and
a third dielectric layer formed on said second RDL;
wherein said first die and said second die respectively having pluralities of pads coupled to said first RDL and said second RDL for electrical connection with each other by said through holes.

2. The structure in claim 1, further comprising contact metals coupled to said first die and said second die through said first RDL and said second RDL.

3. The structure in claim 1, further comprising a cover layer formed on the lower surface of said substrate.

4. The structure in claim 1, further comprising a plurality of soldering bumps formed on said contact metals.

5. The structure in claim 1, further comprising a first die attached material formed between said first die and said substrate.

6. The structure in claim 5, wherein material of said first die attached material includes elastic material.

7. The structure in claim 1, further comprising a second die attached material formed between said first die and said second dielectric layer.

8. The structure in claim 7, wherein material of said second die attached material includes elastic material.

9. The stricture in claim 1, wherein material of said substrate includes epoxy type FR5, FR4 or BT (Bismaleimide triazine).

10. The structure in claim 1, wherein material of said substrate includes metal, alloy, glass, silicon, ceramic or print circuit board (PCB).

11. The structure in claim 10, wherein said alloy includes Alloy 42 (42% Ni-58% Fe) or Kovar (29% Ni-17% Co-54% Fe).

12. The structure in claim 1, wherein said first dielectric layer, said second dielectric layer and said third dielectric layer include an elastic dielectric layer, a photosensitive layer, a silicone dielectric based layer, a siloxane polymer (SINR) layer, a polyimides (PI) layer or silicone resin layer.

13. The structure in claim 1, wherein materials of said first RDL and said second RDL are made from an alloy comprising Ti/Cu/Au alloy or Ti/Cu/Ni/Au alloy.

14. The stricture in claim 1, further comprising a seed metal layer sputtered within said first RDL and said second RDL.

15. A method for forming a semiconductor device package, comprising:
providing a substrate with at least a pre-formed die receiving cavity and terminal contact pads formed within an upper surface of said substrate;
using a pick and place fine alignment system to re-distribute at least a first die on a die redistribution tool with desired pitch, and said die redistribution tool includes adhesive material at the periphery area of said die redistribution tool to adhere said substrate;
attaching an attached material on the back side of said first die;
bonding said substrate on to said die back side, and curing then separating said die redistribution tool from said substrate;
coating a first dielectric layer on said first die and said substrate, followed by performing vacuum procedure;
forming a first re-distribution layer (RDL) on said first dielectric layer and coupling to said first die;
forming a second dielectric layer to cover said first RDL;
attaching a second die on said second dielectric layer covered by core pastes having through holes;
forming a second re-distribution layer (RDL) to couple said second die and fill said through holes to electrical connect to said first RDL; and
forming a third dielectric layer over said second RDL;
wherein said first die and said second die respectively having pluralities of pads coupled to said first RDL and said second RDL can be electrical connected with each other by said through holes.

16. The method in claim 15, further comprising a step of welding a plurality of soldering bumps on said second RDL.

17. The method in claim 15, further comprising a step of forming a cover layer on lower side of said substrate.

18. The method in claim 15, further comprising a step of attaching a second attached material between said second die and said second dielectric layer.

19. The method in claim 15, further comprising a step of sputtering a seed metal layer within said first RDL and said second RDL.

20. The method in claim 15, wherein said die redistribution tool is made of glass, silicon, ceramic, PCB and alloy 42.
